(19) United States
(12) Patent Application Publication
(10) Pub. No.: US 2008/0025004 A1
(43) Pub. Date: Jan. 31, 2008

(54) Method for Producing a Plastic-Coasted Stamped Grid, and Plastic-Coated Stamped Grid

(76) Inventor: Michael Horbelt, Warmbronn (DE)

Correspondence Address: RONALD E. GREIGG;GREIGG & GREIGG P.L.L.C., 1423 POWHATAN STREET, UNIT ONE, ALEXANDRIA, VA, 22314, US

(21) Appl. No.: 11/587,208

(22) PCT Filed: Feb. 9, 2005
(86) PCT No.: PCT/EP05/50562

§ 371 Date: Oct. 23, 2006

(30) Foreign Application Priority Data
Apr. 24, 2004 (DE) 10 2004 020 085.8

(51) Int. Cl. H05K 7/00; B29C 39/00

(52) U.S. Cl. 361/746; 264/299

(57) ABSTRACT

A method for producing a plastic-coated stamped grid, and a grid producer thereby on which components are disposed and which is embedded in a plastic housing in an injection mold, with the stamped grid being fixed at a fixation point with a fixation element, so that the shape of the stamped grid is preserved during the injection molding operation. As the fixation element, a plastic element is used, which is enclosed by the injected plastic, so that it seals off the fixation point. The housing is produced with a first and a second component, and the stamped grid is enclosed completely by the second component, but terminals for mechanically and/or electrically connecting the stamped grid are not enclosed. The first component opens out to a first outer side and to a second outer side of the housing.

### PRIOR ART

The invention is based on a method for producing a plastic-coated stamped grid and on a plastic-coated stamped grid on which preferably electronic components are disposed, as generically defined by the preambles to the independent claims 1 and 8.

In the known method, the stamped grid is embedded in plastic in an injection mold. During the injection molding operation, the stamped grid is as a rule held in position at a plurality of fixation points by fixation elements. The fixation elements are dies, which are disposed in the injection mold and in pairs firmly hold the stamped grid. As a result, the stamped grid is fixed in its shape, so that the shape of the stamped grid is essentially preserved during the injection molding operation. The use of the dies means that the stamped grid is not covered with plastic at these points, which can have adverse effects under aggressive environmental conditions to which the metal of the stamped grid can be exposed.

Plastic-coated stamped grids that are embedded in a housing of plastic are also known. The housing may for instance be produced by the two-component injection molding process, with a first and a second component. The stamped grid is completely spray-coated with the second component, and terminals for mechanical and/or electrical connection of the stamped grid are not enclosed by the second component. With the second component, a seal can for instance be integrally formed on.

### ADVANTAGES OF THE INVENTION

The method of the invention for producing a plastic-coated stamped grid, and the plastic-coated stamped grid itself, on which preferably electronic components are disposed, having the characteristics of independent claims 1 and 8, respectively, have the advantage that places that in use are open unnecessarily in terms of the function of the stamped grid are now closed.

To this end, in the method for producing a plastic-coated stamped grid, on which preferably electronic components are disposed, and the stamped grid is embedded, in at least one injection mold, in a housing of plastic, and during the injection molding operation, the stamped grid is fixed at at least one fixation point by at least one fixation element, so that the shape of the stamped grid is essentially preserved during the injection molding operation, and in which as the at least one fixation element, a plastic element is used; and that the plastic element is at least partly enclosed by injected plastic, so that the fixation point is sealed off.

In a preferred refinement, the plastic element, when it is placed with the stamped grid in the at least one injection mold and the injection mold is closed, rests on a first side of the injection mold and on a second side, diametrically opposite the first side, of the injection mold. As a result, a good seat in the injection mold is obtained. Preferably, the plastic element is held by a press fit in the at least one injection mold.

The best sealing is obtained if the at least one plastic element is at least partly melted, so that the fixation point is sealed.

In a preferred refinement, in a first work step, the at least one plastic element is mounted on the stamped grid and/or a structural part disposed on the stamped grid, and then the stamped grid is placed in the at least one injection mold for the completion of the spray-coating. The result is a more secure method order. Preferably, the first work step is performed in a different injection mold.

Preferably, the at least one plastic element is disposed in the region of an ejector of the at least one injection mold. The result is a relatively smooth surface, to which dirt sticks less.

The plastic-coated stamped grid of the invention, which is embedded in a housing of plastic, has a housing that is produced by the two-component injection molding process, with a first and a second component; the stamped grid is completely spray-coated with the second component, and at least terminals for mechanically and/or electrically connecting the stamped grid are not enclosed by the second component, and in which the first component opens out to a first outer side of the housing and to a second outer side, diametrically opposite the first outer side.

Preferably, the orifices of the first component are aligned with one another. This makes simple visual monitoring in the context of quality control possible.

In a preferred refinement, the first component encloses at least part of the stamped grid. This provides a good hold.

Preferably, the first component is of the same plastic as the second component. As a result, there is no need to perform tests of the miscibility of two different plastics.

Further advantages and advantageous refinements will become apparent from the dependent claims and the description.

### DRAWINGS

One exemplary embodiment is shown in the drawing and described in further detail in the ensuing description. Shown are:

FIG. 1, a view from below of a plastic-coated stamped grid in which a structural part is disposed;

FIG. 2, a front view of FIG. 1 with an example of an injection mold; and

FIG. 3, the stamped grid in a preliminary stage, with a different injection mold.

### DESCRIPTION OF THE EXEMPLARY EMBODIMENT

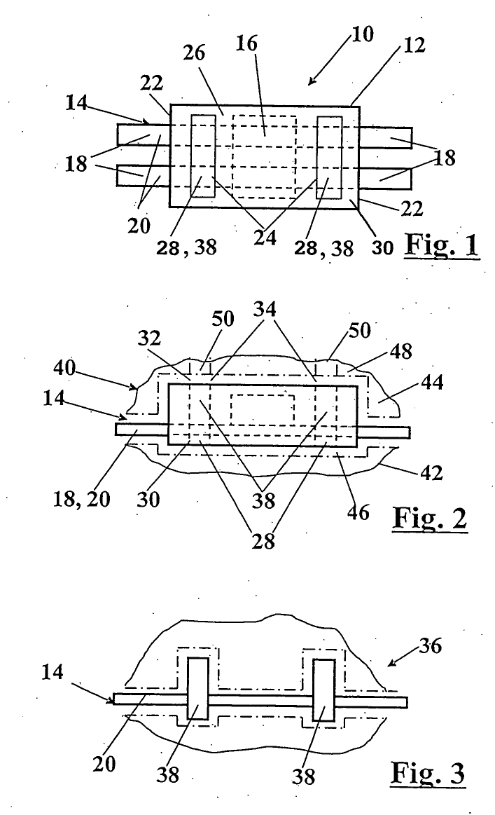

In FIG. 1, an interference suppressor 10 for an electric motor, not shown, is shown from below. The interference suppressor 10 includes a plastic housing 12 and a stamped grid 14, embedded in it, on which a capacitor 16, optionally combined with a resistor, is disposed. The interference suppressor 10 has four terminals 18, which are formed by two parallel strips 20 of the stamped grid 14 that protrude out of the housing 12 on two diametrically opposed long sides 22. It is also conceivable, instead of the relatively simply constructed interference suppressor 10, to provide a complex control unit that has dozens of terminals 18 and a substantially more-complex stamped grid 14, which has many different structural parts rather than merely capacitors 16. It is also possible for no electronic structural parts whatever to be provided, so that the plastic-coated stamped grid 14 is merely in the form of a plug, for instance. However, it is preferable for electronic components to be disposed on the plastic-coated stamped grid 14.

The housing 12 is produced by the two-component injection molding process, with a first component 24 and a second component 26. The two components 24, 26 are preferably of the same plastic. The stamped grid 14 is almost entirely spray-coated with the second component 26, and the terminals 18 for mechanical and/or electrical connection of the stamped grid 14 are not enclosed by the second component 26. The first component 24 is clearly illustrated in FIG. 1 by two rectangular orifices 28 in the underside 30 of the housing 12. The first component 24 opens out to this underside 30, representing a first outer side, of the housing 12 and to the outer side or top side 32 (FIG. 2), diametrically opposite the first outer side.

From FIG. 2 it can also be seen that the orifices 28 in the underside 30 and the orifices 34 in the top side 32 of the first component 24 are aligned in pairs with one another. From the views in FIGS. 1 and 2, it can also be seen that the first component 24 encloses part of the stamped grid 14, because both strips 20 are partly embedded in it.

As indicated in FIG. 3, to produce the interference suppressor 10, the already fabricated stamped grid 14 is placed in an injection mold 36, part of which is represented by dot-dashed lines. The injection mold 36 is shaped such that when the plastic is injected, two plastic elements 38 are made from the first component 24, and these plastic elements fix the two strips 20 in their position relative to one another.

After that, the capacitor 16 is mounted on the stamped grid 14, and the resultant structural unit is placed in a further injection mold 40, also suggested by dot-dashed lines in FIG. 2. When the injection mold 40 is closed by moving the two halves 42, 44 of the injection mold 40 together, the plastic elements 38 rest on two diametrically opposed sides 46, 48 or halves 42, 44 of the injection mold 40. Preferably, the plastic elements 38 are held with a press fit in the injection mold 40. However, it suffices if the plastic elements 38 rest on the sides 46, 48. As a result, optionally upon the next shot, which will now be described, some of the second component 26 can cover the orifices 28, 34.

Once the halves 42, 44 have been moved together, the second component 26 is injected, and the stamped grid 14 in the injection mold 40 is embedded in the plastic of the second component 26. By means of the plastic elements 38, the stamped grid 14 is fixed during the injection molding operation, so that the shape of the stamped grid 14 is essentially preserved during this operation. The plastic elements 38 thus function as fixation elements, which fix the stamped grid 14 at fixation points which correspond to the orifices 28, 34. Once the stamped grid is embedded in the second component 26, the plastic elements 38 are also at least partly enclosed, since the orifices 28, 34 optionally remain exposed, by the injected plastic of the second component 26, so that the fixation point is sealed off.

If the plastic elements 38 are melted at least in the peripheral regions in the second shot, then the fixation points are sealed, which produces the best sealing. Depending on the choice of material for the various components 24, 26, however, this does not happen.

As can also be seen in FIG. 2, the plastic elements 38 are disposed such that they are located in the region of ejectors 50 of the injection mold 40.

As an alternative to the first work step of the spray-coating described in conjunction with FIG. 3, it is possible for instance, instead of the plastic elements 38 produced by spray-coating, to use elements joined by a hinge, which can be mounted on the stamped grid 14 by means of a detent hook connection.

The plastic elements 38 may equally well be secured to the capacitor 16 or to some other structural part disposed on the stamped grid 14. The plastic elements 38 may also be disposed either on a structural part or directly on the stamped grid 14. It is equally conceivable for each of the plastic elements 38 to be embodied in two or more parts, with a first part secured to a structural part while a second or further structural part is secured to the stamped grid 14. Naturally it is also possible for only a single plastic element 38 to be provided. The required number can be determined. Thus the number of possibly visible orifices 28, 34 also varies.

1-11. (canceled)

12. In a method for producing a plastic-coated stamped grid on which preferably electronic components are disposed, and which is embedded, in at least one injection mold in a housing of plastic by injection molding and during the injection molding operation, the stamped grid is fixed at at least one fixation point by at least one fixation element, so that the shape of the stamped grid is essentially preserved during the injection molding operation, the improvement comprising employing a plastic element as the at least one fixation element and at least partly enclosing the plastic element by injected plastic so that the fixation point is sealed off during the injection molding operation.

13. The method as defined by claim 12, wherein the at least one plastic element when it is placed with the stamped grid in the at least one injection mold and the injection mold is closed, rests on a first side of the injection mold and on a second side diametrically opposite the first side of the injection mold.

14. The method as defined by claim 12, wherein the at least one plastic element is held by a press fit in the at least one injection mold.

15. The method as defined by claim 13, wherein the at least one plastic element is held by a press fit in the at least one injection mold.

16. The method as defined by claim 12, wherein the at least one plastic element is at least partly melted during the injection molding operation so that the fixation point is sealed.

17. The method as defined by claim 12, wherein the at least one plastic element is at least partly melted during the injection molding operation so that the fixation point is sealed.

18. The method as defined by claim 13, wherein the at least one plastic element is at least partly melted during the injection molding operation so that the fixation point is sealed.

19. The method as defined by claim 14, wherein the at least one plastic element is at least partly melted during the injection molding operation so that the fixation point is sealed.

20. The method as defined by claim 12, wherein the at least one plastic element in a first work step, is mounted on the stamped grid and/or a structural part disposed on the stamped grid and then the stamped grid is placed in the at least one injection mold for the completion of the housing.

21. The method as defined by claim 13, wherein the at least one plastic element in a first work step, is mounted on the stamped grid and/or a structural part disposed on the stamped grid and then the stamped grid is placed in the at least one injection mold for the completion of the housing.

22. The method as defined by claim 14, wherein the at least one plastic element in a first work step, is mounted on the stamped grid and/or a structural part disposed on the stamped grid and then the stamped grid is placed in the at least one injection mold for the completion of the housing.

23. The method as defined by claim 15, wherein the at least one plastic element in a first work step, is mounted on the stamped grid and/or a structural part disposed on the stamped grid and then the stamped grid is placed in the at least one injection mold for the completion of the housing.

24. The method as defined by claim 20, wherein that the first work step is performed in at least one different injection mold.

25. The method as defined by claim 12, wherein the at least one plastic element is disposed in the region of an ejector of the at least one injection mold.

26. A plastic-coated stamped grid for mounting electronic components and having terminals for mechanical and/or electrical connection, a housing of plastic embedding the grid, the housing with a first component of plastic and a second component of plastic, and the stamped grid with the second component being completely spray-coated and the terminals for mechanically and/or electrically connecting the stamped grid are not enclosed by the second component, the first component including orifices opening out to a first outer side of the housing and to a second outer side diametrically opposite the first outer side.

27. The stamped grid as defined by claim 26, wherein the orifices of the first component are aligned with one another.

28. The stamped grid as defined by claim 26, wherein the first component encloses at least part of the stamped grid.

29. The stamped grid as defined by claim 27, wherein the first component encloses at least part of the stamped grid.

30. The stamped grid as defined by claim 26, wherein the first component is of the same plastic as the second component.
